(19) United States
(12) Patent Application Publication
(10) Pub. No.: US 2001/0013610 A1
(43) Pub. Date: Aug. 16, 2001

(54) VERTICAL BIPOLAR TRANSISTOR BASED ON GATE INDUCED DRAIN LEAKAGE CURRENT

(76) Inventors: MIN-HWA CHI, HSINCHU (TW); MIN-CHIE JENG, CHI-LONG (TW)

Correspondence Address: BLAKELY SOKOLOFF TAYLOR & ZAFMAN LLP, 12400 WILSHIRE BOULEVARD, 7TH FLOOR, LOS ANGLES, CA, 90025

(21) Appl. No.: 09/365,436

(22) Filed: Aug. 2, 1999

(51) Int. Cl. H01L 31/072; H01L 27/082; H01L 31/109

(52) U.S. Cl. 257/197

(57) ABSTRACT

A vertical npn bipolar transistor formed in a p-type substrate is disclosed. The transistor comprises: a deep n-well formed within the p-type substrate; a buried n+ layer formed within the deep n-well; a p-well formed within the deep n-well and atop the buried n+ layer; an isolation structure surrounding the p-well and extending from the surface of the substrate to below the level of the p-well; a n+ structure formed within the p-well; and a gate formed above the p-well, the gate separated from the substrate by a thin oxide layer, the gate extending over at least a portion of the n+ structure. To turn on the npn bipolar transistor, the gate is pulsed to 0 volts (or lower), generating GIDL current at the n+ structure and flowing into the p-well (as base current). A corresponding vertical gated pnp bipolar transistor can also be formed and operated similarly with reverse polarity of charge carriers and biases.

### TECHNICAL FIELD OF THE INVENTION

The present invention relates to bipolar transistor, and more particularly, to a vertical bipolar transistor that is based on gate induced drain leakage (GIDL) current and compatible with CMOS processes.

### BACKGROUND OF THE INVENTION

Conventional CMOS semiconductor devices, such as the n-channel ETOX cell, are often fabricated by a twin-well process or a triple-well process. As seen in FIG. 1, the triple-well process can provide a parasitic vertical pnp 101 bipolar transistor as well as a parasitic vertical npn 103 bipolar transistor. These transistors are typically used for crucial circuit applications (e.g. voltage reference) in CMOS VLSI. The n+ and p+ source and drain structures can serve as the n+ and p+ emitters. The p-well and n-well can act as the bases and the deep n-well and p-substrate as collectors.

These vertical bipolar transistors of the prior art have several limitations. First, they share the same p-substrate or deep n-well as their collectors and therefore can only be configured in “common collector” mode. Second, the bipolar amplification of the pnp 101 and npn 103 are typically less than five in modern CMOS technology (i.e. 0.35 μm and below) due to the limitation of the well depth (as base width) and a retrograded well doping profile (desirable in advanced CMOS process for suppressing latch-up). As an example, the retrograded p-well doping in vertical npn bipolar transistor 103 will result in a built-in field that retards n-type charge carrier (injected from the n+ emitter) transit through the p-well base region. This will reduce the bipolar amplification of the vertical npn bipolar transistor 103 in advanced CMOS technology (i.e. 0.35 μm and below). Similarly, a retrograded n-well doping will reduce the bipolar amplification of the vertical pnp bipolar transistor 101.

What is needed is a new vertical bipolar transistor structure that overcomes the disadvantages of the prior art and still compatible with CMOS processes.

### SUMMARY OF THE INVENTION

A vertical npn bipolar transistor formed in a p-type substrate is disclosed. The transistor comprises: a deep n-well formed within said p-type substrate; a buried n+ layer formed within said deep n-well; a p-well formed within said deep n-well and atop said buried n+ layer; an isolation structure surrounding said p-well and extending from the surface of said substrate to below the level of said p-well; a n+ structure formed within said p-well; and a gate formed above said p-well, said gate separated from said substrate by a thin oxide layer, said gate extending over at least a portion of said n+ structure.

The gate can induce the gate induced drain leakage (GIDL) current, which flows into the base to turn on the vertical npn bipolar transistor. A corresponding vertical pnp bipolar transistor can also be formed and operated similarly.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-section of a semiconductor substrate showing parasitic bipolar transistors in a prior art twin-well and triple-well structure;

FIG. 2 is a cross-section of a semiconductor substrate showing an npn vertical bipolar transistor formed in accordance with the present invention;

FIG. 3 is a qualitative graph of the vertical doping profile of the npn bipolar transistor of FIG. 2;

FIG. 4 is a detail of the bipolar transistor of FIG. 2 during the turn-on operation;

FIG. 5 is a cross-section of a semiconductor substrate showing a pnp vertical bipolar transistor formed in accordance with the present invention; and

FIG. 6 is a detail of the bipolar transistor of FIG. 5 during the turn-on operation.

### DETAILED DESCRIPTION OF THE PREFERRED EMBODIMENT

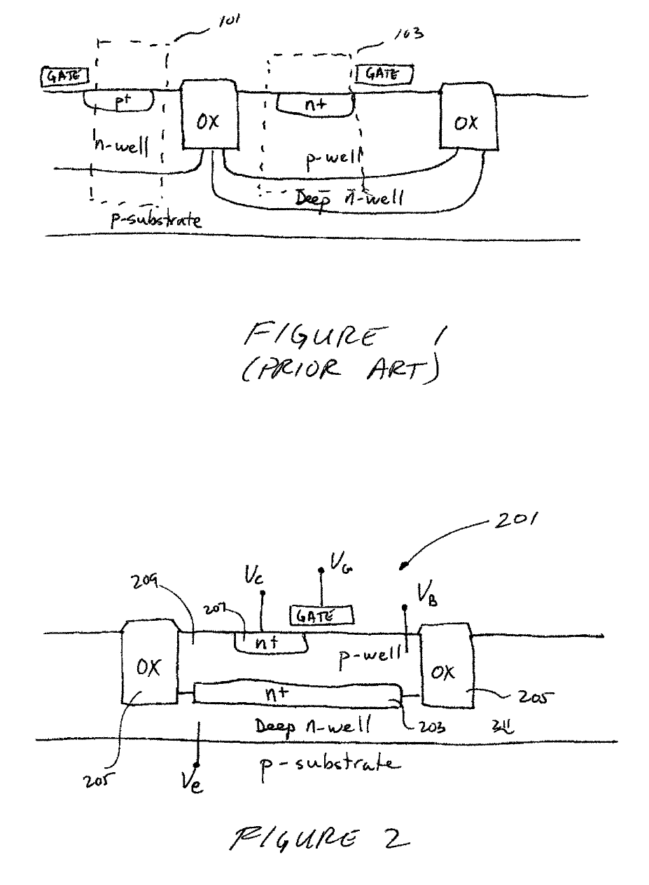

Turning to FIG. 2, a vertical gated npn bipolar transistor 201 formed in accordance with the present invention has three additional features compared to the conventional parasitic npn bipolar transistor 103 cell shown in FIG. 1. First, a buried n+ layer 203 is formed underneath the p-well 209 and above the deep n-well 211. Second, oxide trench isolations 205 are formed for isolating the p-well 209. Third, the gate is formed to overlay both the n+ region 207 (the collector) and the p-well 209 (the base). Note also that there is no need for a base contact for the turn-on operation described below. In addition, there is also no need for a lightly doped drain (LDD) implant and spacer in the gated base-collector structure, which will be used for GIDL generation for the turn-on operation. The lightly doped drain structure would only suppress the GIDL generation.

The buried n+ layer 203 can be easily formed by using an additional masking step (opening the bipolar transistor cell area after the deep n-well is defined) and high energy ion implant of an n-type dopant (e.g. P³¹ or As). As will be seen with greater detail below, the implant process must be carefully designed to achieve three goals: (1) small base width (for larger gain), (2) higher emitter doping than the p-well doping (for high injection efficiency), and (3) less total P³¹ dose (for less damage by the high energy implant). The buried n+ layer 203 is preferably implemented by P³¹ with multiple energies (500 Kev and 750 Kev) with doses of about 1E15 each on current triple-well 0.35 micron CMOS technology. The buried n+ layer 203 together with the deep n-well will serve as the emitter for the bipolar transistor 201. The p-well 209 serves as the base and the n+ region 207 as the collector. Thus, the gated npn bipolar transistor 201 will be used in “common emitter” configuration and turned-on by GIDL current from the gated base-collector (p-well and n+) structure.

The trench isolations 205 preferably extend deeper than the p-well depth (approx. 1 micron). The trench isolations 205 can be formed by a masking step for a trench etch at the front end of the fabrication process. In comparison, typical shallow trench isolation structures for 0.35 μm CMOS transistors extend only about 0.3-0.5 μm deep. Thus, trench isolations 205 for isolating p-wells can also be used as shallow trench isolation structures for CMOS transistors. The trench isolation technique will result in smaller spacing and is therefore preferred. In any case, the trench isolations 205 must be at least slightly deeper than the p-well depth.

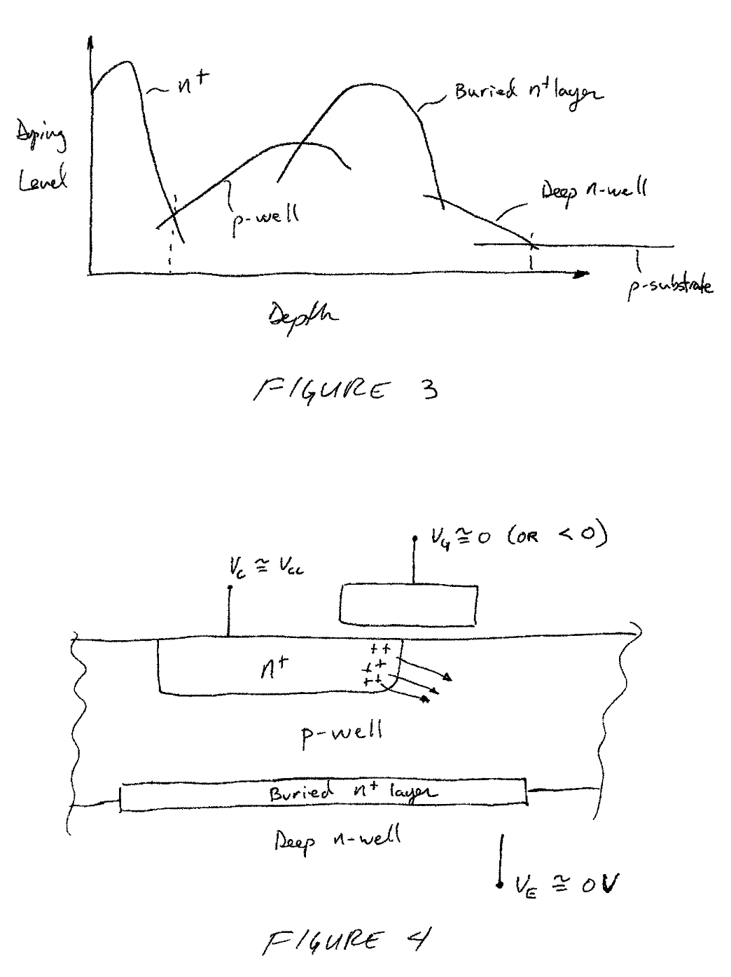

The dose and energy of the buried n+ layer 203 will determine the position of the emitter junction and the bipolar amplification gain (β) of the bipolar action. The bipolar action can be maximized by higher electron injection efficiency (from the buried n+ layer to the p-well) with a smaller base (p-well) width (in the vertical dimension). One preferred design is shown in FIG. 3, where the buried n+ layer is close to and with doping ten times higher than the peak doping level of the retrograded p-well (for good electron injection efficiency). The effective base width (e.g. <0.5 microns) is therefore smaller than the p-well depth (approx. 1 micron) for increasing the β of the parasitic bipolar. The retrograded p-well doping can result in a built-in field for assisting transiting through the base and further increasing β. By using these design considerations, the β of the vertical bipolar transistor 201 can be significantly higher (e.g. >10) than prior art parasitic CMOS bipolar transistors.

The npn transistor 201 can be turned on by GIDL current, as seen in more detail in FIG. 4. Initially, when the transistor 201 is off, the collector is biased at a higher potential than the emitter: V_{E}≅0 volts and V_{C}≅V_{cc}, where V_{cc} is the external power supply, typically 3.3 volts for 0.35 CMOS technology. The gate potential V_{G} is biased to the highest potential +V_{cc}. Note that the base (p-well) is left floating and its potential is clamped to that of the n+ buried layer.

When the transistor 201 is to be turned on, V_{G} is pulsed down to the lowest potential, e.g. 0 volts or lower. This causes the surface of the n+ collector to generate holes by the band-to-band tunneling mechanism. See H. Wann, P. Ko, and C. Hu, “Gate Induced Band-to-Band Tunneling Leakage Current in LDD MOSFETs”, Technical Digest of Int'l Electron Device Meetings, Paper No. 6.5, pages 147-150, 1992. The holes will flow into the base (the p-well) as base current by the field in the depletion region at the n+ collector to p-well junction. The base-to-emitter junction (i.e. p-well to n+ buried layer) is thus forward biased and the bipolar action is triggered.

The transistor 201 can be turned off by pulsing the gate to high (+V_{cc}) so that there is no GIDL current flowing into the base (i.e. base current terminated). The gated vertical bipolar transistor is therefore turned off by an “open base” turn-off mechanism.

The speed of the bipolar transistor turn-on is based on the magnitude of the GIDL current. In order to maximize the GIDL current at the gated n+/p-well base junction, the usual lightly doped drain implant and spacer are not needed, since they will only suppress the GIDL generation, and therefore slow down the turn-on operation.

The transistor 201 can also be used as a conventional bipolar transistor by adding a base contact and removing the gate overlap over the collector/base junction. Furthermore, the n+ region 207 and the n+ buried layer 203 can be interchangeably used as either the collector or the emitter; therefore, the transistor 201 can be used in both common emitter and common collector configuration based on the need of the circuit.

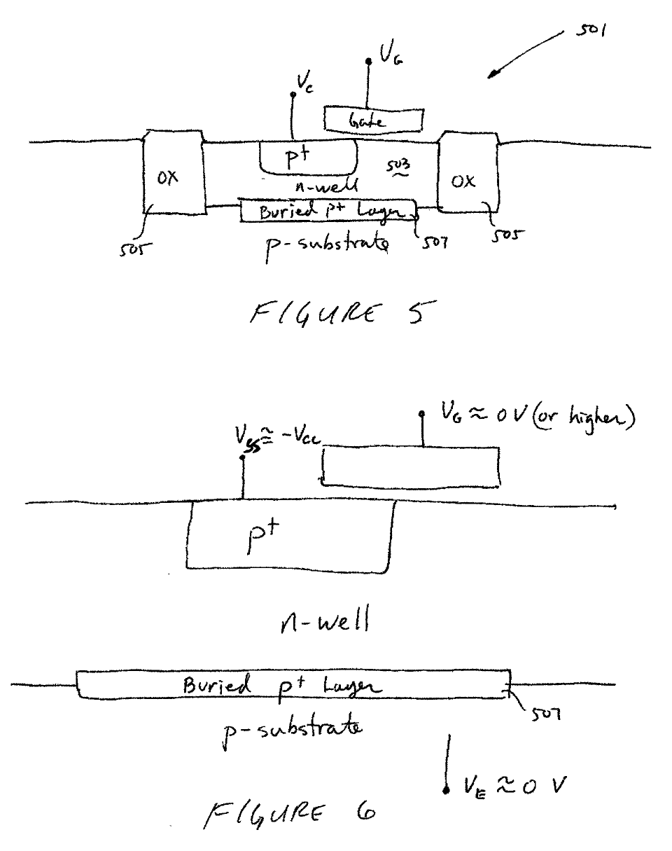

FIG. 5 shows the pnp version of a vertical gated pnp bipolar transistor 501. The transistor is formed by the p+ well/n-well/p-substrate. Notice that the depth of the n-well 503 is almost the same as that of the p-well, therefore, the trench isolation 505 can also be used for isolating the n-wells 503. The pnp gated bipolar transistor 501 exists in twin-well or triple-well process with the additional feature of the buried p+ layer 507.

The pnp transistor 501 can be turned on by GIDL current, as seen in more detail in FIG. 6. Initially, when the transistor 501 is off, the collector is biased at a lower potential than the emitter: V_{E}≅0 volts and V_{C}≅V_{cc}, where −Vₛₛ is the negative power supply from external or generated on-chip. The gate potential V_{G} is biased to the lowest potential −Vₛₛ. Note that the base (n-well) is left floating and its potential is clamped to that of the p+ buried layer 507.

When the transistor 501 is to be turned on, V_{G} is pulsed up to 0 volts or higher. This causes the surface of the p+ collector to generate electrons by the band-to-band tunneling mechanism. The electrons will flow into the base (the n-well) as base current by the field in the depletion region at the p+ collector to n-well junction. The emitter-to-base junction (i.e. n-well to p+ buried layer) is thus forward biased and the bipolar action is triggered.

The transistor 501 can be turned off by pulsing the gate back to low (−Vₛₛ) so that there is no GIDL current flowing into the base (i.e. base current terminated). The gated vertical bipolar transistor is therefore turned off by an “open base” turn-off mechanism.

While the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A vertical npn bipolar transistor formed in a p-type substrate comprising:
a deep n-well formed within said p-type substrate;
a buried n+ layer formed within said deep n-well;
a p-well formed within said deep n-well and atop said buried n+ layer;
an isolation structure surrounding said p-well and extending from the surface of said substrate to below the level of said p-well;
a n+ structure formed within said p-well; and
a gate formed above said p-well, said gate separated from said substrate by a thin oxide layer, said gate extending over at least a portion of said n+ structure.

2. The transistor of claim 1 wherein said buried n+ layer is formed using a high energy implanter so that the buried n+ layer has a higher dopant concentration than said p-well.

3. The transistor of claim 1 wherein the transistor is turned on by:
biasing said deep n-well to 0 volts;
biasing said gate to no more than 0 volts;
leaving said p-well floating; and
biasing said n+ structure to a positive voltage.

4. The transistor of claim 1 wherein the transistor is turned off by:
biasing said deep n-well to 0 volts;
biasing said gate to +V_{cc};
leaving said p-well floating; and
biasing said n+ structure to a positive voltage.

5. The transistor claim 1 wherein said isolation structure is a trench isolation.

6. A vertical pnp bipolar transistor formed in a p-type semiconductor substrate comprising: a buried p+ layer formed within said substrate;
an n-well formed within said p-type substrate and atop said buried p+ layer;
an isolation structure surrounding said n-well and extending from the surface of said substrate to below the level of said n-well;
a p+ structure formed within said n-well; and
a gate formed above said n-well, said gate separated from said substrate by a thin oxide layer, said gate extending over at least a portion of said p+ structure.

7. The transistor of claim 6 wherein said buried p+ layer is formed using a high energy implanter so that the buried p+ layer has a higher dopant concentration than said deep n-well.

8. The transistor of claim 6 wherein the transistor is turned on by:
biasing said p-type substrate to 0 volts;
biasing said gate to greater than or equal to 0 volts;
leaving said n-well floating; and
biasing said p+ structure to a negative voltage.

9. The transistor of claim 1 wherein the transistor is turned off by:
biasing said p-type substrate to 0 volts;
biasing said gate to −Vₛₛ;
leaving said p-well floating; and
biasing said n+ structure to a negative voltage.

10. The transistor claim 6 wherein said isolation structure is a trench isolation.
